(19) United States
(12) Patent Application Publication
(10) Pub. No.: US 2026/0231691 A1
(43) Pub. Date: Aug. 6, 2026

(54) PHASE-CHANGE MATERIAL MEMORY DEVICES AND METHODS OF FORMING THE SAME

(71) Applicant: Taiwan Semiconductor Manufacturing Company Limited, Hsinchu (TW)

(72) Inventors: Kuo-Pin Chang, Zhubei City (TW); Yu-Wei Ting, Taipei City (TW); Kuo-Ching Huang, Hsinchu City (TW); Hung-Ju Li, Hsinchu City (TW)

(21) Appl. No.: 19/046,990

(22) Filed: Feb. 6, 2025

(51) Int. Cl. H10N 70/20; H10B 63/00; H10B 63/10; H10N 70/00

(52) U.S. Cl. CPC H10N 70/231; H10B 63/10; H10B 63/20; H10B 63/30; H10N 70/021; H10N 70/063; H10N 70/066; H10N 70/068; H10N 70/253; H10N 70/841; H10N 70/8613; H10N 70/8828; H10N 70/883

(57) ABSTRACT

Phase-change memory devices and methods of fabricating the same. In some embodiments, a phase-change memory device includes a bottom electrode, a top electrode, and a phase-change material disposed between the top electrode and the bottom electrode. The phase-change material is configured to switch between an amorphous state and a crystalline state in response to heating. The phase-change memory device includes a liner extending from the bottom electrode along at least one side of the phase-change material to the top electrode. The phase-change memory device includes a heater comprising a vertical portion of the liner extending upward from the bottom electrode toward the phase-change material. The phase-change memory device includes a spacer positioned adjacent to the vertical portion of the liner.

### BACKGROUND

A phase-change material random-access memory (PCM or PCRAM) is a form of non-volatile random-access computer memory. PCRAM technology is based upon a material that may be either amorphous or crystalline at normal ambient temperatures. During conditions in which the material is in the amorphous state, the material has a high electrical resistance. The amorphous state may be referred to as a high resistance state (HRS). During conditions in which the material is in the crystalline state, the material has a low electrical resistance. The crystalline state may be referred to as a low resistance state (LRS). Thus, the state of the material may allow the PCRAM's to store a charge and serve as a memory device.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a phase-change material random-access memory (PCRAM) structure including a phase-change memory cell and a field effect transistor, according to various embodiments.

FIG. 2 is a schematic view of a PCRAM structure including multiple phase-change memory cells, according to various embodiments.

FIG. 3 is a vertical cross sectional view of a memory device including a PCRAM and a field effect transistor (FET), according to various embodiments.

FIG. 4 is a schematic block diagram of a memory circuit including a PCRAM and a field effect transistor (FET), according to various embodiments.

FIG. 5A is a vertical cross-sectional view of a PCRAM device including a phase-change material memory cell and an adjacent phase-change material memory cell, according to various embodiments.

FIG. 5B is a vertical cross-sectional view of an embodiment phase-change material memory cell having a SiN spacer.

FIG. 5C is a vertical cross-sectional view of an embodiment phase-change material memory cell having a TiN spacer.

FIG. 5D is a vertical cross-sectional view of an embodiment phase-change material memory cell with a circuit diagram overlayed on the memory cell.

FIG. 5E is a vertical cross-sectional view of an embodiment phase-change material memory cell with a circuit diagram overlayed on the memory cell.

FIG. 6 is a graph illustrating the resistance characteristics of the phase-change material memory cell under specific operating conditions, in accordance with some embodiments.

FIGS. 7A-7P illustrate a process for forming a phase-change material memory cell in accordance with some embodiments.

FIG. 8A is a vertical cross-sectional view of an alternative embodiment phase-change material memory cell.

FIG. 8B illustrates a vertical cross-sectional view of an alternative embodiment phase-change material memory cell having a TiN spacer with a circuit diagram overlayed over the embodiment phase-change material memory cell.

FIG. 8C illustrates a vertical cross-sectional view of an alternative embodiment phase-change material memory cell having a TiN spacer in the HRS with a circuit diagram overlayed over the embodiment phase-change material memory cell.

FIGS. 9A-9E illustrate a process for forming a phase-change material memory cell in accordance with some embodiments.

FIG. 10 illustrates a flow diagram of an example method for fabricating a phase-change material memory device according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

A phase-change material random-access memory (PCM or PCRAM) is a form of non-volatile random-access computer memory. PCRAM technology is based upon a material that may be either amorphous or crystalline at normal ambient temperatures (i.e., phase change material). During conditions in which the material is in the amorphous state, the material has a high electrical resistance. The amorphous state may be referred to as a high resistance state (HRS). During conditions in which the material is in the crystalline state, the material has a low electrical resistance. The crystalline state may be referred to as a low resistance state (LRS).

In order to control the state of the material, the material may be heated and cooled. By heating the material above its crystallization point, the material enters its crystalline state. The material may be heated, for example, by passing current through a heating element. As the material cools, it enters an amorphous state. The change of phase in a PCRAM cell and the resulting change in electrical resistance may be used to store data in the PCRAM cell.

To change the phase of the PCRAM cell, a SET operation switches the material of the PCRAM cell to the crystalline phase and a RESET operation switches the material of the PCRAM into the amorphous phase. The SET operation crystallizes the material of the PCRAM by heating it above its crystallization temperature, and the RESET operation melt-quenches the material of the PCRAM to make the material amorphous. The SET operation and the RESET operation may be associated with different electrical current profiles or voltage profiles, such as one type of pulses for the RESET operation that heat the material of the PCRAM above its melting temperature and another type of pulses for the SET operation to heat the material of the PCRAM its crystallization temperature but below its melting temperature.

Examples of the phase-change materials may be, but are not limited to, chalcogenide materials, such as germanium-antimony-tellurium (GeSbTe or GST) materials (e.g., Ge₂Sb₂Te₅, GeTe—Sb₂Te₃, etc.), and/or aluminum-antimony materials (e.g., Al₅₀Sb₅₀, etc.). Other suitable chalcogenide materials are within the contemplated scope of this disclosure. A PCRAM may include many memory cells that operate independently. A PCRAM cell may include a heater and a resistor.

The PCRAM cell may operate as a data storage element made mainly of a reversible phase-change material to provide at least two different resistivities for logical “0” state and “1” states. To read a state (data) from the PCRAM cell, a sufficiently small current is applied to the phase-change material without triggering the heater to generate heat. In this way, the resistivity of the phase-change material may be measured and the states representing the resistivities, that is, a “0” state for high resistivity or a “1” state for low resistivity, for example, may be read.

To write a state (data) in the PCRAM cell, for example, to write a “1” state representing a low resistivity phase of the phase-change material, a medium electric current may be applied to the heater which generates heat for annealing the phase-change material at a temperature above the crystallization temperature but below the melting temperature of the phase-change material for a time period to achieve a crystalline phase. As the phase-change material heats to a temperature above the crystallization temperature, the material may enter a crystalline state where the phase-change material exhibits a low electrical resistance. With the low resistance value, a charge may flow into the material to establish the “1” state value.

To write a “0” state representing a high resistivity phase of the phase-change material, a large electric current may be applied to the heater to generate heat to melt the phase-change material at a temperature higher than the melting temperature of the phase-change material; and the electric current is abruptly cut off to lower the temperature to below the crystallization temperature of the phase-change material to quench and stabilize the amorphous structure of phase-change material. As the phase change material enters the amorphous state, the phase-change material exhibits a high resistance value. The high resistance value may represent a “0” state value. The large electric current may thus be in a pulse form.

PCRAM cells may have the ability to achieve a number of distinct intermediary states, thereby having the ability to hold single bits in a single cell supporting a single-level-cell (SLC) mode or multiple bits in a single cell, such as two bits supporting a multiple-level-cell (MLC) mode. In a SLC mode, the PCRAM may sometimes be referred to as a SLC type memory structure. In a MLC mode, the PCRAM may sometimes be referred to as a MLC type memory structure. In a SLC mode, the PCRAM may fluctuate between a high resistance state (HRS) in response to a RESET operation and a low resistance state (LRS) in response to a SET operation. In a MLC mode, the PCRAM may be controlled to achieve one of multiple intermediate states between the HRS and the LRS in response to a RESET operations and the LRS in response to the SET operation.

Phase-change memory devices according to some embodiments of the present disclosure may achieve a larger memory window, high-reliability resistance states, and lower required write power. The phase-change memory devices may achieve these advantages by virtue of a small heater fabricated as part of a liner for low power operation. The large memory window and low power requirement may be useful, for example, in MLC operations.

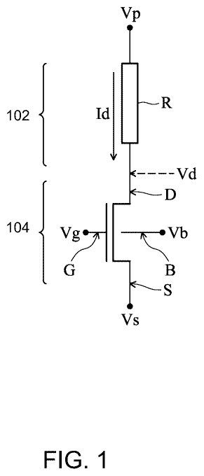

FIG. 1 is a schematic view of a PCRAM structure 100 constructed according to an embodiment. The PCRAM structure 100 may include one phase-change material memory cell 102 and a current-controlling device 104 connected together. The phase-change material memory cell 102 includes a phase-change material layer interposed between two electrodes, as described in greater detail below. In some embodiments, the resistance of the phase-change material layer may be configured to be adjusted into multiple levels that represent different logic states, respectively. In embodiments in which a phase-change material layer is configured to be adjusted into multiple levels that represent different logic states, respectively, the PCRAM structure 100 may be considered to be operating in a MLC mode. In some embodiments, the resistance of the phase-change material layer may be configured to be adjusted to a single level that represent a single logic state. In scenarios in which a phase-change material layer is configured to be adjusted to a single level that represent a single logic state, the PCRAM structure 100 may be considered to be operating in a single-level-cell (SLC) mode.

The current-controlling device 104 in the PCRAM structure 100 may be a device that is operable to control the current flow through the phase-change material memory cell 102 (also referred to as a PCRAM cell 102) during the operations. In the present embodiment, the current-controlling device 104 may be a transistor (or selector transistor), such as a field effect transistor (FET). For example, the FET 104 may be a metal-oxide-semiconductor (MOS) FET. The FET 104 includes source(S), drain (D) and gate (G). The source S and drain D may be designed asymmetrically, such that a voltage drop over the FET during a forming operation and an off-state leakage current may be collectively optimized. The source S and drain D may separately formed, so that the source S and drain D may be independently tuned to achieve the asymmetric structure. More particularly, the source S and drain D may be different from each other in term of doping concentration. In various embodiments, the source and drain may be different in at least one of doping concentration, doping profile, and doping species.

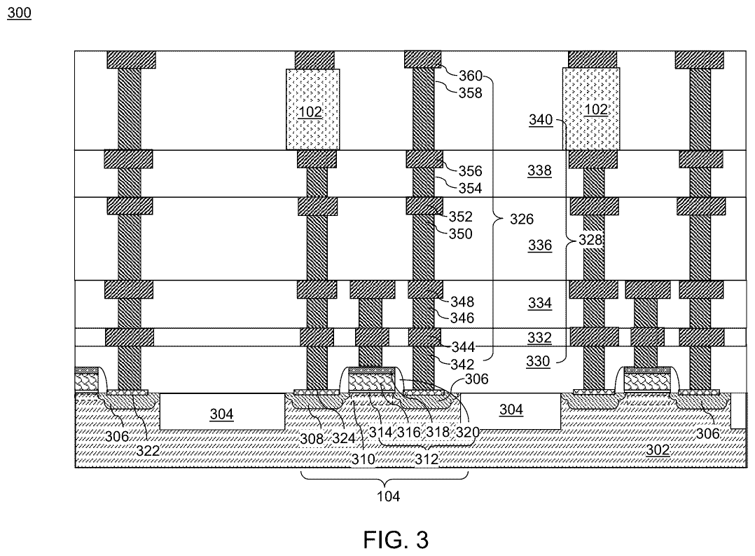

The FET 104 may be electrically coupled with the phase-change material memory cell 102. In an embodiment, one electrode of the phase-change material memory cell 102 may be connected to the drain D of the FET 104. The gate G of the FET 104 may be connected to a word line, and another electrode of the me phase-change material memory cell 102 may be connected to a bit line, as described in greater detail with reference to FIG. 3, below.

As illustrated in FIG. 1, the gate, source, drain, and body of the FET 104 are labeled as G, S, D, and B, respectively. The corresponding voltages of the gate, source, drain and substrate during the operations are labeled as Vg, Vs, Vd, and Vb, respectively. Furthermore, during operation, the current through the phase-change material memory cell 102 is labeled as Id, and the voltage applied to one electrode of phase-change material memory cell 102 from the bit line is labeled as Vp.

In one embodiment, the PCRAM structure 100 may be a two terminal memory structure, with the gate of the FET 104 operating as a first terminal, and one electrode of the phase-change material memory cell 102 operating as a second terminal. The first terminal is controlled by a first voltage applied to the gate G of FET 104 from the word line, and the second terminal is controlled by a second voltage applied to the one electrode of the phase-change material memory cell from the bit line. In one example, the source is grounded, and the body of the FET 104 is grounded or floating.

In another embodiment, the PCRAM structure 100 may be a three terminal memory structure, wherein the three terminals include the gate of FET 104 as a first terminal, the electrode of the phase-change material memory cell 102 (the electrode that is not directly connected with the drain of the transistor) as a second terminal, and the source of the FET 104 as a third terminal. Particularly, during the operations of the phase-change material memory cell 102, the first terminal (gate) may be controlled by a first voltage from the word line, the second terminal may be controlled by a second voltage from the bit line, and the third terminal may be controlled by a third voltage from a source line. In one example, the source is grounded. In an alternative example, the second terminal is grounded. The substrate (or the body) of the FET 104 may be grounded or floating.

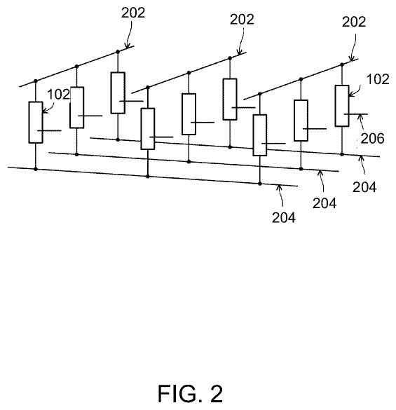

FIG. 2 is a schematic view of a memory structure 200 having a plurality of phase-change material memory cells 102 constructed according various embodiments. With reference to FIGS. 1 and 2, the phase-change material memory cells 102 may be configured in an array coupled with a plurality of word lines 202 and a plurality of bit lines 204. In one embodiment, the word lines 202 and the bit lines 204 may be cross-configured. Furthermore, each of the phase-change material memory cells 102 may be operable to achieve single resistance levels and accordingly single bit storage (e.g., in a SLC mode) and/or multiple resistance levels and accordingly multiple bit storage (e.g., in a MLC mode). In this example embodiment, source lines 206 are configured to connect to the sources of the phase-change material memory cells 102, respectively.

The source lines 206 may be configured such that one source line 206 is coupled with one respective phase-change material memory cells 102. Alternatively, one source line may be coupled with a subset of the phase-change memory cells 102 in the memory structure 200. In some embodiments, the memory structure 200 may be configured such that all phase-change material memory cells 102 operate in a SLC mode at a given time. In some embodiments, the memory structure 200 may be configured such that all phase-change material memory cells 102 operate in a MLC mode at a given time. In some embodiments, the memory structure 200 may be configured to be partitionable such that one or more phase-change material memory cells 102 operate in a SLC mode and one or more phase-change material memory cells 102 operate in a MLC mode at a given time.

FIG. 3 is a cross sectional view of a memory device 300, according to various embodiments. With reference to FIGS. 1 to 3, the memory device 300 may include one or more phase-change material memory cells 102 and corresponding field effect transistors (FETs) 104, disposed on a substrate 302. The memory device 300 may include a two-dimensional array of memory cells arranged in a one transistor-one resistor (1T1R) configuration, that is, a configuration in which one access transistor is connected to one resistive memory cell.

The substrate 302 may be a semiconductor substrate such as a commercially available silicon substrate. Alternatively, or additionally, the substrate 302 may include elementary semiconductor materials, compound semiconductor materials, and/or alloy semiconductor materials. Examples of the elementary semiconductor materials may be, but are not limited to, crystal silicon, polycrystalline silicon, amorphous silicon, germanium, and/or diamond. Examples of the compound semiconductor materials may be, but are not limited to, silicon carbide, gallium arsenic, gallium phosphide, indium phosphide, indium arsenide, and/or indium antimonide. Examples of alloy semiconductor materials may be, but are not limited to, SiGe, GaAsP, AlInAs, AlGaAs, GaInAs, GaInP, and/or GaInAsP. Other suitable materials within the contemplated scope of this disclosure may also be used.

The FETs 104 may provide functions that are needed to operate the phase-change material memory cells 102. Specifically, the FETs 104 may be configured to control the programming operation, the erase operation, and the sensing (read) operation of the phase-change material memory cells 102. In some embodiments, the memory device 300 may include sensing circuitry and/or a top electrode bias circuitry on the substrate 302. The FETs 104 may include complementary metal-oxide-semiconductor (CMOS) transistors. While the embodiment illustrated in FIG. 3 illustrates a CMOS transistor, other FET transistors such as fin FET, thin-film transistors (TFT), etc., may be used as well. The substrate 302 may optionally include additional semiconductor devices (such as resistors, diodes, capacitors, inductors, etc.).

Shallow trench isolation structures 304 including a dielectric material such as silicon oxide may be formed in an upper portion of the substrate 302. Suitable doped semiconductor wells, such as p-type wells and n-type wells may be formed within each area that is laterally enclosed by a continuous portion of the shallow trench isolation structures 304. Accordingly, the FETs 104 may be formed on the substrate 302 between the isolation structures 304, such that the FETs 104 may be electrically isolated from one another by the isolation structures 304.

Each FET 104 may include a source region 306, a drain region 308, a semiconductor channel 310 that includes a surface portion of the substrate 302 extending between the source region 306 and the drain region 308, and a gate structure 312. Each gate structure 312 may include a gate dielectric 314, a gate electrode 316, a gate cap dielectric 318, and a dielectric gate spacer 320. A source-side metal-semiconductor alloy region 322 may be formed on each source region 306, and a drain-side metal-semiconductor alloy region 324 may be formed on each drain region 308.

In some embodiments, the channel region 310 may be doped with a first type dopant, and the source region 306 and the drain region 308 may be doped with a second type dopant, opposite to the first type. In this example embodiment, the FET 104 may be an n-type FET (nFET). Accordingly, the channel region 310 may be p-type channel.

In one embodiment, the source region 306 may be formed by a first ion implantation process, and the drain region 308 may be formed by a second ion implantation process. The second ion implantation process may be different from the first ion implantation process in at least one of doping dose, implanting angle and dopant (doping species). In one embodiment, the first ion implantation process may include forming a first patterned mask on the substrate, and applying the first ion implantation to the substrate using the first patterned mask as an implantation mask. The first patterned mask may include an opening such that a substrate region for the source is uncovered thereby. The first patterned mask may be a patterned photoresist layer formed by a lithography process, or alternatively, a patterned hard mask formed by lithography process and etching. Similarly, the second ion implantation process may include forming a second patterned mask on the substrate, and applying the second ion implantation to the substrate using the second patterned mask as an implantation mask. The second patterned mask may include an opening such that a substrate region for the drain is uncovered thereby. The second patterned mask may be similar to the first patterned mask in terms of formation and composition.

Various metal interconnect structures 326 formed in dielectric material layers 328 may be formed over the substrate 302 and the devices formed thereon (such as the FETs 104). The dielectric material layers may include, for example, a contact-level dielectric material layer 330, a first metal-line-level dielectric material layer 332, a second line-and-via-level dielectric material layer 334, a third line-and-via-level dielectric material layer 336, a fourth line-and-via-level dielectric material layer 338, and a fifth line-and-via-level dielectric material layer 340.

The metal interconnect structures 326 may be formed by performing any suitable deposition process, such as a chemical vapor deposition (CVD) process, a physical vapor deposition (PVD) process, an atomic layer deposition (ALD) process, a high density plasma CVD (HDPCVD) process, a metal organic CVD (MOCVD) process, an electroplating process, or a plasma enhanced CVD (PECVD) process.

The metal interconnect structures may include device contact via structures 342 formed in the contact-level dielectric material layer 330 and that contact respective component of the FETs 104, first metal lines 344 formed in the first metal-line-level dielectric material layer 332, first metal via structures 346 formed in a lower portion of the second line-and-via-level dielectric material layer 334, second metal lines 348 formed in an upper portion of the second line-and-via-level dielectric material layer 334, second metal via structures 350 formed in a lower portion of the third line-and-via-level dielectric material layer 336, third metal lines 352 formed in an upper portion of the third line-and-via-level dielectric material layer 336, third metal via structures 354 formed in a lower portion of the fourth line-and-via-level dielectric material layer 338, fourth metal lines 356 formed in an upper portion of the fourth line-and-via-level dielectric material layer 338, fourth metal via structures 358 formed in a lower portion of the fifth line-and-via-level dielectric material layer 340, and fifth metal lines 360 formed in an upper portion of the fifth line-and-via-level dielectric material layer 340. In one embodiment, the metal interconnect structures 326 may include source lines that are connected a source-side power supply for an array of memory elements. The voltage provided by the source lines may be applied to the bottom electrodes through the access transistors provided in the memory array region 102.

Each of the dielectric material layers (330, 332, 334, 336, 338, 340) may include a dielectric material such as undoped silicate glass, a doped silicate glass, organosilicate glass, amorphous fluorinated carbon, porous variants thereof, or combinations thereof. Each of the metal interconnect structures (342, 344, 346, 348, 350, 352, 354, 356, 360) may include at least one conductive material, which may be a combination of a metallic liner layer (such as a metallic nitride or a metallic carbide) and a metallic fill material. Each metallic liner layer may include TiN, TaN, WN, TiC, TaC, and WC, and each metallic fill material portion may include W, Cu, Al, Co, Ru, Mo, Ta, Ti, alloys thereof, and/or combinations thereof. Other suitable materials within the contemplated scope of this disclosure may also be used.

In one embodiment, the first metal via structures 342 and the first metal line 344 may be formed as integrated line and via structures by a dual damascene process, the second metal via structure 346 and the second metal lines 348 may be formed as integrated line and via structures by a dual damascene process, the third metal via structures 350 and the third metal lines 352 may be formed as integrated line and via structures by a dual damascene process, the fourth metal via structures 354 and the fourth metal lines 356 may be formed as integrated line and via structures by a dual damascene process, and/or the fifth metal via structures 358 and the fourth metal lines 356 may be formed as integrated line and via structures by a dual damascene process.

In some embodiments, the phase-change material memory cells 102 may be disposed within the fifth dielectric material layer 340, and each memory cell 102 may be electrically connected to a respective fourth metal line 356 and a fifth metal line 360. However, the present disclosure is not limited to any particular location for the phase-change material memory cells 102. For example, the phase-change material memory cells 102 may be disposed within any of the dielectric material layers 328.

The metal interconnect structures 326 may be configured to connect each phase-change material memory cell 102 to a corresponding FET 104, and to connect the FET 104 to corresponding signal lines. For example, the drain region 308 of the FET 104 may be electrically connected to a bottom electrode of the phase-change material memory cell 102 via, for example, a subset of the metallic via structures (342, 346, 350, 354) and a subset of the metal lines (344, 348, 352, 356). Each drain region 308 may be connected to a first node (such as a bottom node) of a respective phase-change material memory cell 102 via a respective subset of the metal interconnect structures 326. The gate electrode 316 of each FET 104 may be electrically connected to a word line, which may be embodied as a subset of the metal interconnect structures 326. A top electrode of each phase-change material memory cell 102 may be electrically connected to a respective bit line, which comprises a respective subset of the metal interconnect structures. Each source region 306 may be electrically connected to a respective source line, which comprises a respective subset of the metal interconnect structures. While only five levels of metal lines are illustrated in FIG. 3, it is understood that more metal line levels may be formed above the illustrated levels of FIG. 3. Further, it is understood that the levels in which the source lines, word lines, and bit lines are formed may be selected based on design parameters.

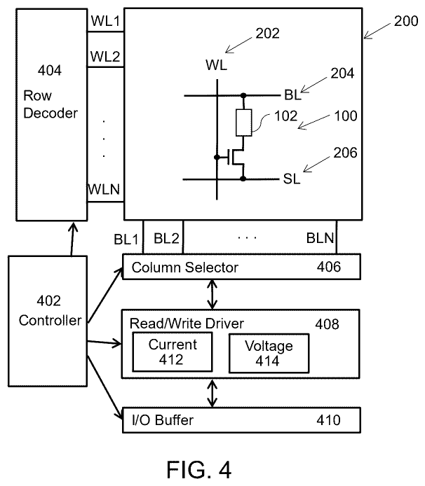

FIG. 4 is a block diagram of a memory circuit 400, according to various embodiments. With reference to FIGS. 1 to 4, the memory circuit 400 may be configured to implement various embodiment methods for configuring a memory structure, such as a PCRAM cell 102 of a PCRAM structure 100. The memory circuit 400 may be configured to control an operating mode (e.g., SLC mode and/or MLC mode) of the PCRAM structure that is part of a memory structure, such as a PCRAM cell 102 of a PCRAM structure 100 (e.g., see FIG. 1), which is part of a memory structure 200 having a plurality of PCRAM cells 102 (e.g., see FIG. 2), and/or to control the RESET program conditions used in programming the PCRAM structure 100. Only a single PCRAM structure 100 is illustrated in FIG. 4 for ease of illustration, but additional structures 100 may be included in the memory structure 200, as described above with reference to FIG. 2.

The memory circuit 400 may include a controller 402, a row decoder 404, a column selector 406, a read/write driver 408, and one or more input/output (I/O) buffers 410. In various embodiments, the controller 402 may be coupled to the row decoder 404 and the column selector 406. In various embodiments, the row decoder 404 may be coupled to the word lines (WL), such as word lines 202 of the memory structure 200, as described above with reference to FIG. 2.

The memory structure 200 may include any number of WLs 1-N, where N is an integer. The column selector 406 may be coupled to the bit lines (BL), such as bit lines 204 discussed above, of the memory structure 200. The memory structure 200 may include any number of BLs 1-N, where N is an integer. The controller 402 may additionally be coupled to the read/write driver 408 and/or the one or more I/O buffers 410. The one or more I/O buffers 410 and read/write driver 408 may be coupled to one another and/or coupled to the column selector 406. The controller 402 may receive various signals from external circuitry related to the circuit 400. For example, the controller 402 may receive commands, such as configuration change commands, from a host controller or processor to transition a PCRAM cell 102 from a SLC mode of operation to a MLC mode of operation or from a MLC mode of operation to a SLC mode of operation.

The controller 402 may determine a type of a received configuration change command to determine whether the received configuration change command is a SLC mode to MLC mode type configuration change command or a MLC to SLC mode type configuration change command. The controller 402 may transmit signals to the row decoder 404, column selector 406, and/or read/write driver 408 to cause the row decoder 404, column selector 406, and/or read/write driver 408 to perform operations to change the states of the PCRAM cells 102 and/or to sense the states of the PCRAM cells 102. For example, the controller 402 may transmit signals to the row decoder 404, column selector 406, and/or read/write driver 408 to cause the row decoder 404, column selector 406, and/or read/write driver 408 to perform operations to perform READ, SET, and/or RESET operations for the PCRAM cells 102 and/or to sense the current of the PCRAM cell 102 (e.g., I_{cell}).

In various embodiments, the controller 402 may select different RESET program conditions based at least in part on a determined type of a received configuration change command. For example, a RESET program condition configured to generate a waveform with a selected current amplitude and/or pulse width may be selected in response to determining that a received configuration change command is a SLC mode to MLC mode type configuration change command. A different RESET program condition configured to generate a waveform with another selected current amplitude and/or another pulse width may be selected in response to determining that a received configuration change command is a MLC mode to SLC mode type configuration change command.

In various embodiments, the controller 402 may transmit signals to the row decoder 404, column selector 406, and/or read/write driver 408 to cause the row decoder 404, column selector 406, and/or read/write driver 408 to perform operations to program the PCRAM cell 102 using the selected RESET program conditions. In various embodiments, the read/write driver 408 may include a current sensing circuit 412 and a voltage sensing circuit 414. In various embodiments, the read/write driver 408, and/or the current sensing circuit 412 specifically, may be configured to apply a selected read voltage (e.g., V_{read}) to a PCRAM cell 102, and the current sensing circuit 412 may be configured to sense the resulting cell current (I_{cell}). In various embodiments, the read/write driver 408, and/or the current sensing circuit 412 specifically, may be configured to store the sensed cell current (I_{cell}) in the one or more I/O buffers 410. In various embodiments, the read/write driver 408, and/or the voltage sensing circuit 414 specifically, may be configured to apply a selected read current (e.g., I_{read}) to a PCRAM cell 102, and the voltage sensing circuit 414 may be configured to sense the resulting cell voltage (V_{cell}). In various embodiments, the read/write driver 408, and/or the voltage sensing circuit 414 specifically, may be configured to store the sensed cell voltage (V_{cell}) in the one or more I/O buffers 410.

In various embodiments, the one or more I/O buffers 410 may be one or more buffers providing storage for current sensing and/or voltage sensing results of the memory structure 200, such as I_{cell}, V_{cell}, etc. Additionally, the one or more I/O buffers 410 may store other values, such as results of comparing current sensing and/or voltage sensing (e.g., I_{cell}, V_{cell}, etc.) to stored threshold values, threshold values themselves (e.g., verification current conditions, verification voltage conditions, etc.), RESET program conditions (e.g., waveform attributes, such as current amplitudes, pulse widths, etc.), etc. In various embodiments, the one or more I/O buffers 410 may be configured to output values, such as I_{cell}, V_{cell}, threshold values, RESET program conditions, etc., to other circuitry, such as the controller 402 and/or other external circuitry related to the memory circuit 400.

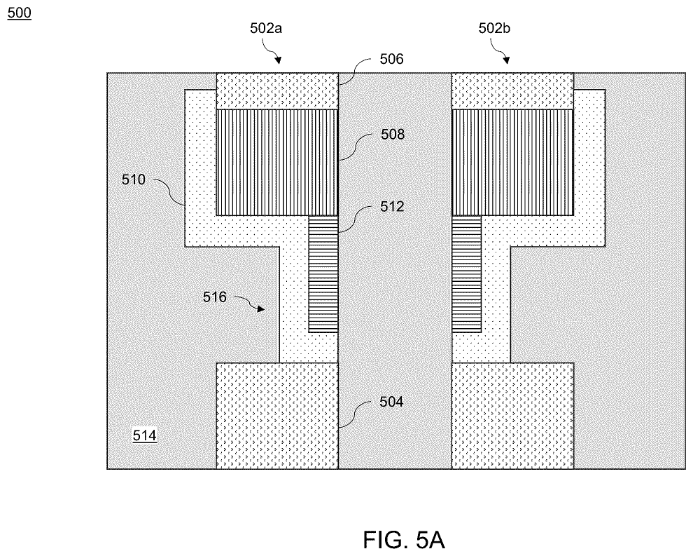

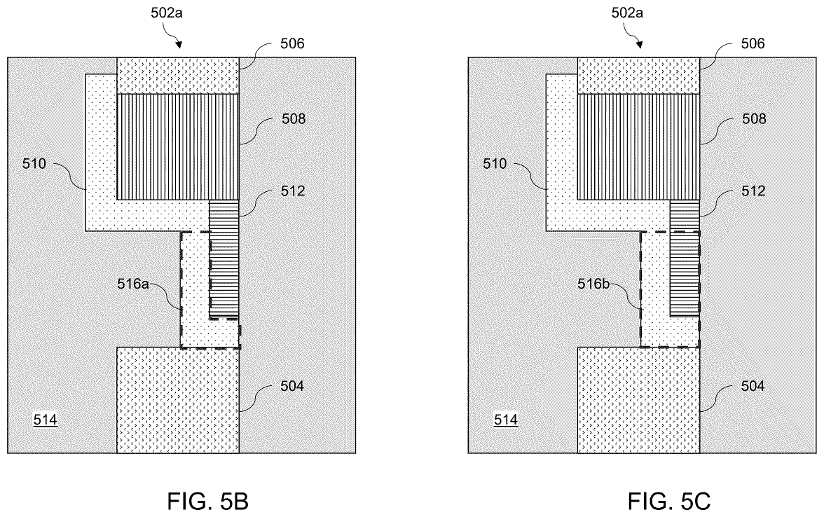

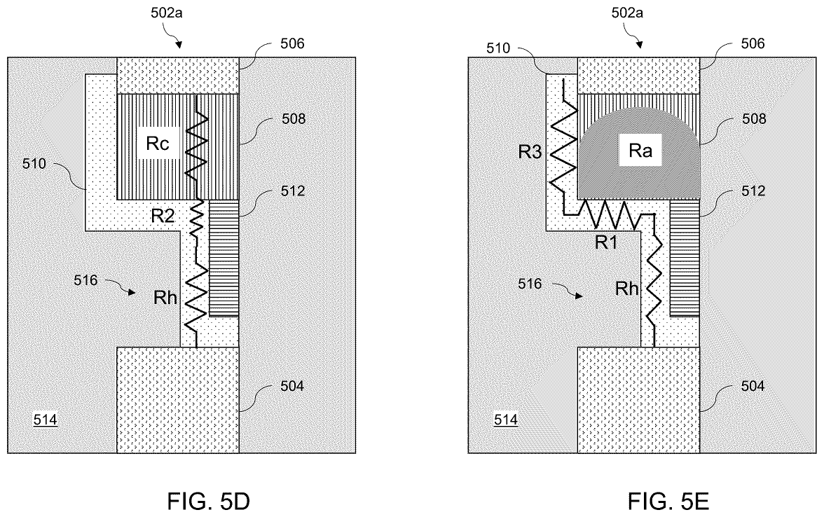

FIG. 5A is a vertical cross-sectional view of a phase-change material memory device 500 including a phase-change material memory cell 502a (also referred to as a PCRAM cell 502a) and an adjacent phase-change material memory cell 502b, according to various embodiments. The adjacent phase-change material memory cell 502b may have a structure that mirrors the phase-change material memory cell 502a in a horizontal direction.

The PCRAM cell 502a may include a bottom electrode 504, a top electrode 506, and a phase-change material 508 disposed between the top electrode 506 and the bottom electrode 504. The phase-change material 508 may be configured to switch between an amorphous state and a crystalline state in response to heating. The PCRAM cell 502a may include a liner 510 and a spacer 512, and the PCRAM cell 502a may be surrounded by an oxide layer 514. The PCRAM cell 502a may include a heater 516.

Each of the bottom electrode 504 and the top electrode 506 may comprise a conductive material. For example, each of the bottom electrode 504 and the top electrode 506 may include W, Cu, Al, Co, Ru, Mo, Ta, Ti, alloys thereof, and/or combinations thereof. Other suitable metallic fill materials within the contemplated scope of this disclosure may also be used.

The phase-change material 508 may be, but is not limited to, a chalcogenide material, such as a germanium-antimony-tellurium (GeSbTe or GST) material (e.g., Ge2Sb2Te5, GeTe—Sb2Te3, etc.), and/or aluminum-antimony material (e.g., Al50Sb50, etc.). Other suitable chalcogenide materials are within the contemplated scope of this disclosure.

The liner 510 may comprise a high-resistivity and non-switchable material. The material for the liner 510 may be chosen to generate heat via Joule heating and to maintain stable properties during normal operation of the PCRAM cell 502a. For example, the liner 510 may comprise a metal oxide, a metallic nitride, or a metallic carbide. Examples of metal oxides include tantalum oxide, titanium oxide, and aluminum oxide. Examples of metallic nitrides include tantalum nitride and titantium nitride (in higher-resistivity forms or doped configurations). Examples of metallic carbide include titanium carbide and tantalum carbide. In some embodiments, the liner comprises a material with a resistivity in the range of 0.1 to 100 ohm·cm. Other suitable liner materials within the contemplated scope of this disclosure may also be used.

In operation, the liner 510 may contribute to heat generation through its high resistivity, which enables localized heating via Joule heating in instances in which electrical current flows through it. The liner 510 may stabilize the high-resistance state (HRS) of the PCRAM cell 502a since the liner 510 is comprised of a non-switchable material with stable electrical properties that do not change during operation. The liner 510 may also provide structural integrity to the PCRAM cell 502a.

The spacer 512 may be formed from silicon nitride (SiN), a highly resistive and thermally insulating material, or titanium nitride (TiN), a conductive material with tunable resistivity. Other suitable spacer materials within the contemplated scope of this disclosure may also be used.

In embodiments in which SiN is used as a spacer 512 material, the spacer 512 may act as a thermal barrier, confining heat generated by the heater 516 to the phase-change material 508 and preventing unwanted thermal dissipation to adjacent regions. This thermal barrier property enhances the efficiency of the phase-change process and promotes thermal stability within the PCRAM cell 502a. In contrast, a TiN spacer provides a conductive pathway that may contribute to the heating function by partially forming the heater 516 itself. TiN's relatively low resistivity allows it to assist in current flow, enabling efficient Joule heating while potentially lowering the required voltage for operation. The choice between SiN and TiN as spacer 512 materials depends on the specific performance objectives of the PCRAM cell 502a, such as prioritizing thermal confinement with SiN or optimizing electrical conductivity and power efficiency with TiN.

The heater 516 may be positioned adjacent to the phase-change material 508, for example, between the bottom electrode 504 and the phase-change material 508. The heater 516 may be configured to generate heat in instances in which a current is passed through the heater 516. For example, the heater 516 may have a resistance R that generates heat per unit time given by P=I²R. The heater 516 may be configured to generate heat sufficient to induce a phase change in the phase-change material 508.

In some embodiments, the liner 510 may have a thickness in a range from approximately 45 nm to approximately 55 nm. The spacer 512 may have a width in the range from approximately 45 nm to approximately 55 nm. The top electrode 506 may have a width/diameter of approximately 50 nm and a height of approximately 20 nm, the phase-change material 508 may have a width/diameter of approximately 55 nm and a height of approximately 35 nm, and the bottom electrode 504 may have a width/diameter of approximately 60 nm and a height of approximately 20 nm.

FIG. 5B is a vertical cross-sectional view of an embodiment of the PCRAM cell 502a having a SiN spacer 512. In the illustrated embodiment of FIG. 5B, the heater 516a comprises a portion of the liner 510 extending vertically upwards from the bottom electrode 504 towards the phase-change material 508. The SiN spacer 512, being highly resistive, does not conduct electricity and therefore does not form part of the heater 516a.

FIG. 5C is a vertical cross-sectional view of an embodiment of the memory cell 502a having a TiN spacer 512. In the illustrated embodiment, the heater 516b comprises the portion of the liner 510 extending vertically upwards from the bottom electrode 504 and also some or all of the TiN spacer 512. The TiN spacer 512, having a relatively lower resistivity, conducts electricity and forms part of the heater 516b.

FIG. 5D is a vertical cross-sectional view of the PCRAM cell 502a with a circuit diagram overlaid on the PCRAM cell 502a, in accordance with some embodiments. The circuit diagram illustrates three resistors: a resistor, Rh, that represents the resistance of the heater 516 portion; a resistor, R2, that represents the resistance of the liner 510 portion directly beneath the phase-change material 508; and a resistor, Rc, that represents the resistance of the phase-change material 508 in the crystalline state (LRS). In the LRS, the total resistance between the bottom electrode 504 and the top electrode 506 is the sum of these resistances, i.e., so that the total resistance is Rc+R2+Rh.

FIG. 5E is a vertical cross-sectional view of the memory cell 502a with a circuit diagram overlaid on the PCRAM cell 502a, in accordance with some embodiments. The circuit diagram illustrates three resistors: a resistor, Rh, that represents the resistance of the heater 516 portion; a resistor, R1, that represents the resistance of the liner 510 portion directly underneath the phase-change material 508; and a resistor, R3, that represents the resistance of the liner 510 portion to the side of the phase-change material 508. The phase-change material 508 is in the amorphous state (HRS) such that current flows around the phase-change material 508 instead of through the phase-change material 508. Thus, the total resistance between the bottom electrode 504 and the top electrode 506 is the sum of the resistances, i.e., so that the total resistance is Rh+R1+R3.

The phase-change material 508 in the amorphous state may have a resistance Ra. To ensure proper operation of the PCRAM cell 502a, the liner 510 and the phase-change material 508 may be configured such that Ra>R1 or R2. The liner 510 may also be configured such that R3>Rh>Rc so that current flow preferentially through the phase-change material 508 in the crystalline state.

FIG. 6 is a graph 600 illustrating the resistance characteristics of the PCRAM cell 502a under specific operating conditions, in accordance with some embodiments. The graph compares the performance of the PCRAM cell 502a with that of some prior designs. The X-axis represents the resistance measured during a read operation, where a read bias voltage (+Vread) is applied to the top electrode, and the bottom electrode is grounded (GND). The resistance is a function of both the temperature, due to the temperature coefficient of resistance (TCR) effect, and the applied bias, as influenced by the current-voltage (I-V) characteristics of the device. The measurements are conducted under the same read bias and temperature conditions.

The graph 600 illustrates that the PCRAM cell 502a provides a larger memory window than the prior designs. The memory window is defined as the difference in resistance between the high-resistance state (HRS) and the low-resistance state (LRS), with the HRS being primarily determined by the liner 510 material's properties. The increased memory window enhances the distinguishability between these states, enabling more reliable data storage and retrieval. Additionally, the graph illustrates improved resistance stability, as the HRS and LRS of the embodiment structures exhibit less drift over time or with repeated read operations compared to prior designs.

This improved performance may be a result of the integration of a high-resistivity, non-switchable liner 510 and the selective use of spacer 512 materials such as titanium nitride (TiN) or silicon nitride (SiN). The liner 510 stabilizes the HRS by providing consistent thermal and electrical characteristics, while the spacer 512 material further optimizes the heater's 516 functionality. These features may be useful, for example, to achieve a balance of low power consumption, enhanced data retention, and reduced susceptibility to environmental or operational fluctuations.

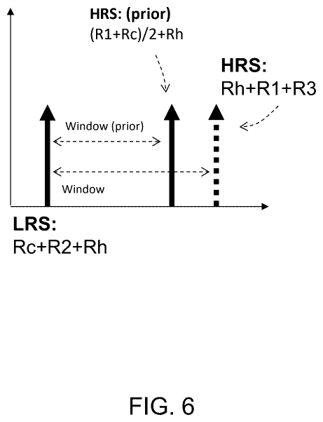

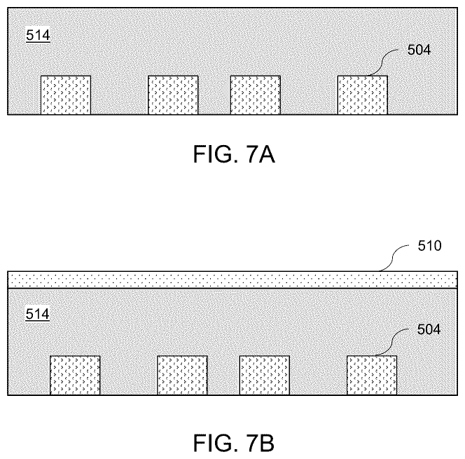

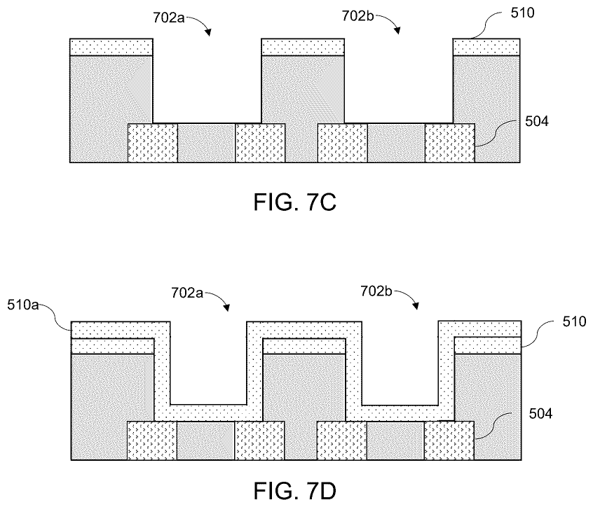

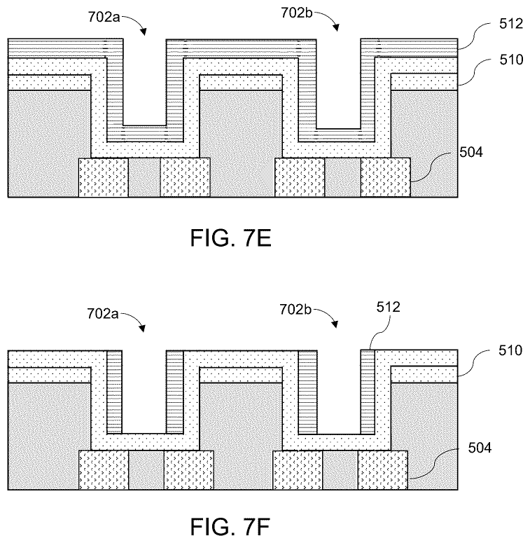

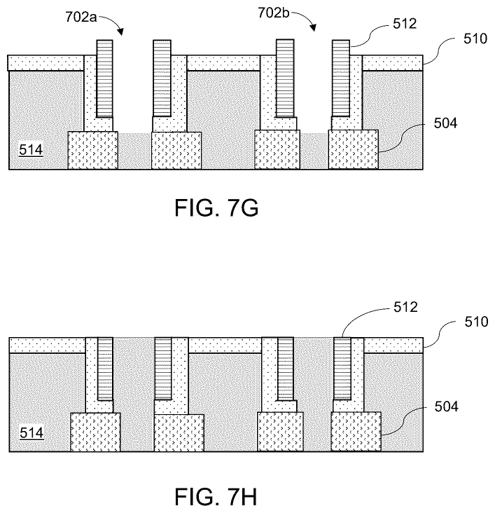

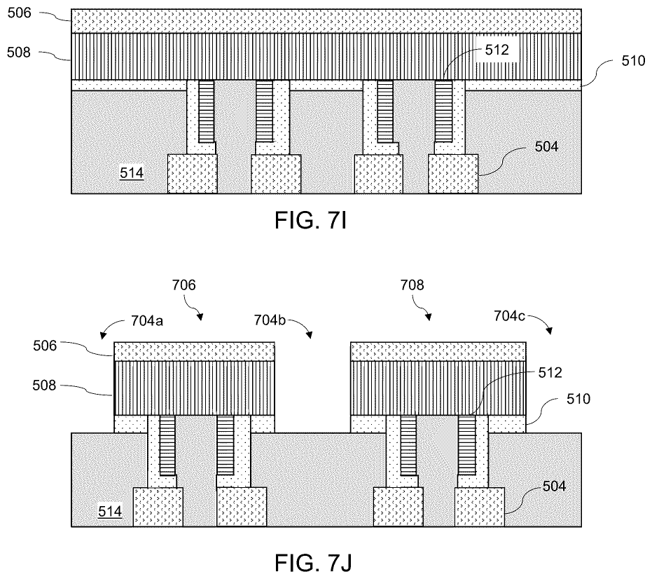

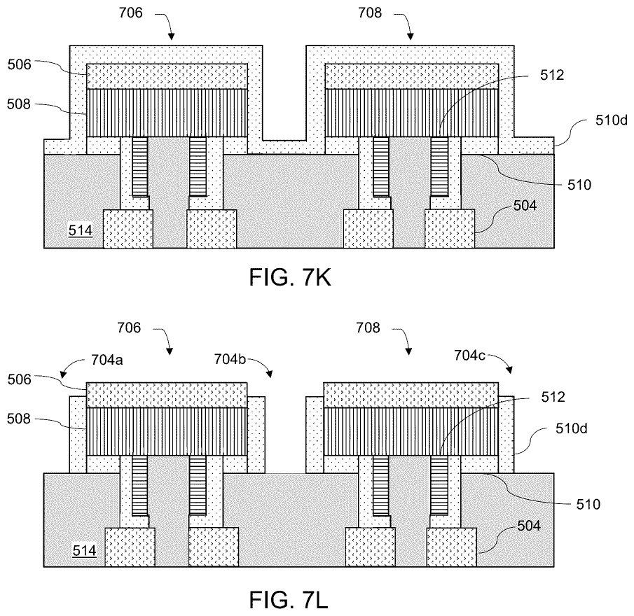

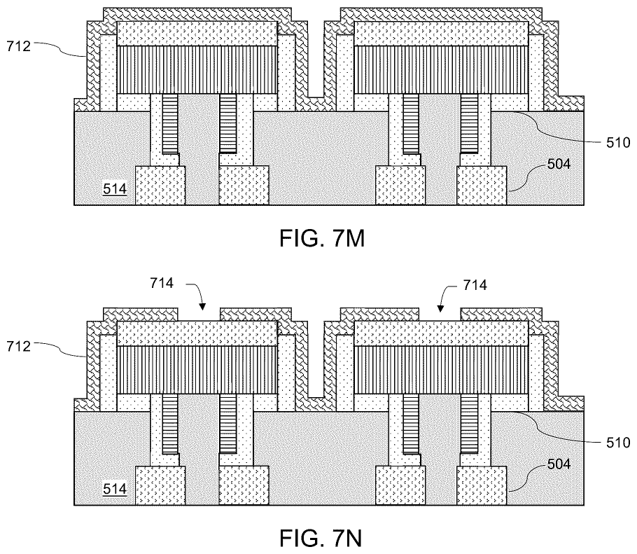

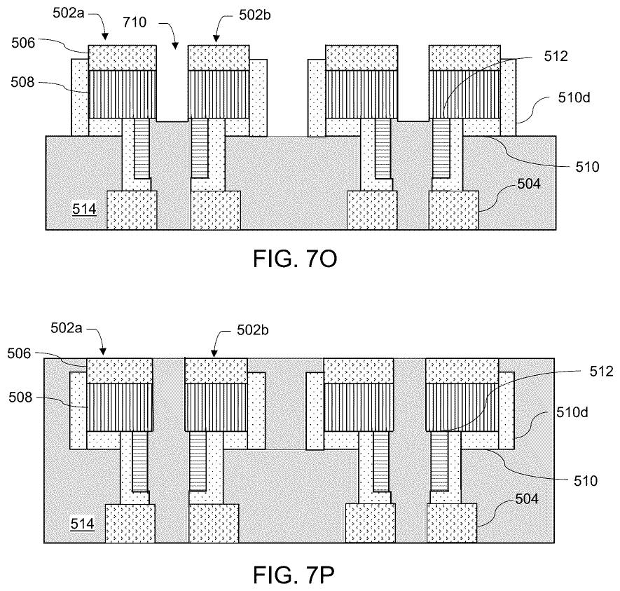

FIGS. 7A-7P illustrate a process for forming the PCRAM cell 502a, in accordance with some embodiments. FIGS. 7A-7P illustrate the process by showing vertical cross-sectional views of various intermediate structures formed during performance of the process.

FIG. 7A illustrates the formation of bottom electrodes 504 and deposition of an oxide layer 514 around the electrodes. The bottom electrodes 504 may be formed on a substrate (not shown). The bottom electrodes 504 may be formed, for example, by electrodeposition. FIG. 7B illustrates the deposition of the liner 510 over the top of the oxide layer 514.

FIG. 7C illustrates patterning and etching of the liner 510 as well the oxide layer 514 for heater fabrication. Openings 702a, 702b may be formed in the liner 510 and the oxide layer 514, extending down to the tops of the bottom electrodes 514. The openings 702a, 702b may be formed using any suitable patterning and etching processes. For example, photolithography may be used to define the desired locations and dimensions of the openings 702a, 702b, followed by etching processes such as reactive ion etching (RIE) or wet chemical etching to remove portions of the liner 510 and the oxide layer 514.

FIG. 7D illustrates a second deposition of liner material 510a. The additional liner material 510a may cover the sides and bottoms of the openings 702a, 702b and may also cover the top of the portions of the liner 510 that were not etched.

FIG. 7E illustrates the deposition of the spacer 512. For example, SiN or TiN may be deposited. The spacer 512 at this stage may cover the sides and bottoms of the openings 702a, 702b and may cover the top of the liner 510. For example, the spacer 512 may be formed using a conformal deposition process, such as chemical vapor deposition (CVD) or atomic layer deposition (ALD), to ensure uniform coverage over the sidewalls and bottoms of the openings 702a and 702b, as well as the top surface of the liner 510. The conformal nature of these processes may enable the spacer material to closely follow the contours of the underlying features.

FIG. 7F illustrates etching of the spacer 512. The spacer material above the liner 510 and at the bottoms of the openings 702a, 702b may be removed, leaving the spacer material on the sides of the openings 702a, 702b. For example, etching of the spacer 512 may be achieved through anisotropic etching, which may selectively remove the spacer material from horizontal surfaces, such as the bottom of the openings 702a, 702b and the top of the liner 510, while preserving the material along the vertical sidewalls of the openings 702a, 702b. The anisotropic etching process may include reactive ion etching (RIE), which may use directional ions and reactive gases to achieve high precision and uniformity.

FIG. 7G illustrates etching of the additional liner material 510a and the liner 510 that may remove some of the additional liner material 510a and the liner 510, including the portion of the liner 510 at the bottoms of the openings 702a, 702b. The oxide layer 514 may be exposed at the bottoms of the openings 702a, 702b. Since the etching may selectively remove liner material and not spacer material, the top of the spacer 512 may extend above the top of the remaining liner 510 until planarization makes the top of the spacer 512 co-planar with the top of the liner 510.

FIG. 7H illustrates oxide deposition and planarization. The oxide deposition may result in filling the openings 702a, 702b with the same material as the rest of the oxide layer 514. Planarization may be performed using any appropriate method, for example, chemical mechanical planarization (CMP). Planarization results in the top surfaces of the liner 510, spacer 512 and oxide layer 514 being co-planar with one another. This may provide a substantially co-planar flat top of the surface of the intermediate structure.

FIG. 7I illustrates deposition of the phase-change material 508 on top of the intermediate structure and deposition of the top electrode 506 on top of the phase-change material 508. The phase-change material 508 may be deposited, for example, using a thin-film deposition technique, such as sputtering or chemical vapor deposition (CVD). The top electrode 506 may be deposited using any appropriate technique for deposition of a conductive material.

FIG. 7J illustrates patterning and etching to define a first pair of memory cells 706 and a second pair of memory cells 708. For example, the top electrode 506 may be patterned by depositing a photoresist (not shown) over the top electrode 506 and patterning the photoresist using photolithographic techniques. The patterned photoresist may then be used as a mask for etching the top electrode 506, the phase-change material 508, and the liner 510, for example, using an anisotropic etching process that is selective to the oxide layer 514. The patterned photoresist may then be removed by ashing or by dissolution with a solvent.

The etching creates openings 704a, 704b, and 704c in the intermediate structure. The first opening 704a and the second opening 704b define the first pair of memory cells 706, and the second opening 704b and the third opening 704c define the second pair of memory cells 708.

FIG. 7K illustrates deposition of another layer 510d of liner material, adding to the liner 510. As a result, the phase-change material 508 and top electrode 506 may be embedded by the liner 510.

FIG. 7L illustrates etching of the layer 510d of liner material to expose the tops of the top electrodes 506. The top of the liner 510 may be etched to a depth below that of the tops of the top electrodes 506. For example, the etching process may be anisotropic, such as reactive ion etching (RIE), to enable directional removal of the liner material from horizontal surfaces (e.g., the exposed portions within the openings 704a, 704b, 704c), while minimizing impact on vertical surfaces. The etching parameters may be configured to selectively remove the linter material without damaging the oxide layer 514 and the top electrode 506.

FIG. 7M illustrates deposition of a masking layer 712 such as a photoresist. The masking layer 712 may be deposited over the oxide layer 514, the liner 510, and the top electrode 506. FIG. 7N illustrates patterning of the masking layer 712 to create openings 714 in the masking layer 712 that may be subsequently used to define individual memory cells. Photolithography may be used to pattern the masking layer 712.

FIG. 7O illustrates etching to define the PCRAM cell 502a and the adjacent memory cell 502b. An opening 710 is formed through the top electrode 506 and the phase-change material 508. The opening 710 in the top electrode 506 and the phase-change material 508 may be formed through the opening 714 in the masking layer 712 while the masking layer 712 protects other areas of the intermediate structure. The remaining masking layer 712 may be removed using a stripping process, such as wet or dry etching.

The opening 710 may be etched to a depth below the bottom of the phase-change material 508 to prevent electrical conduction between the phase-change material 508 in the memory cell 502a and the phase-change material 508 in the adjacent memory cell 502b. Any suitable processes for patterning and etching may be used to form the opening 710 and thereby define the memory cell 502a and the adjacent memory cell 502b.

For example, an anisotropic etching process, such as reactive ion etching (RIE), may be used to selectively remove the exposed portion of the top electrode 506, the phase-change material 508, and the oxide layer 514 while the protected regions remain intact.

FIG. 7P illustrates the PCRAM cell 502a after oxide deposition and planarization. The oxide layer 514 may surround the sides of the PCRAM cell 502a and the adjacent PCRAM cell 502b. For example, the oxide material may be deposited using plasma-enhanced chemical vapor deposition (PECVD) or low-pressure chemical vapor deposition (LPCVD) to ensure conformal coverage of the underlying topography. The deposition may provide a sufficient thickness of the oxide material to fill any voids or trenches between structures.

The planarization results in a flat top of the resulting structure. Any suitable process for planarization may be used. For example, chemical mechanical polishing (CMP) may be used to create a flat surface.

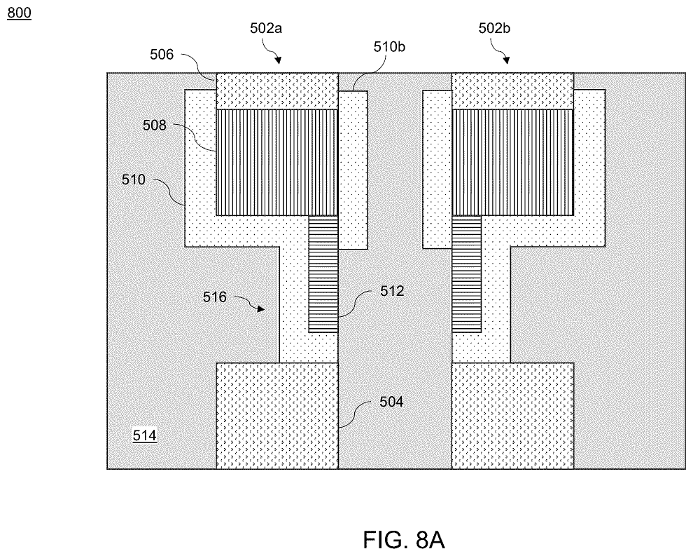

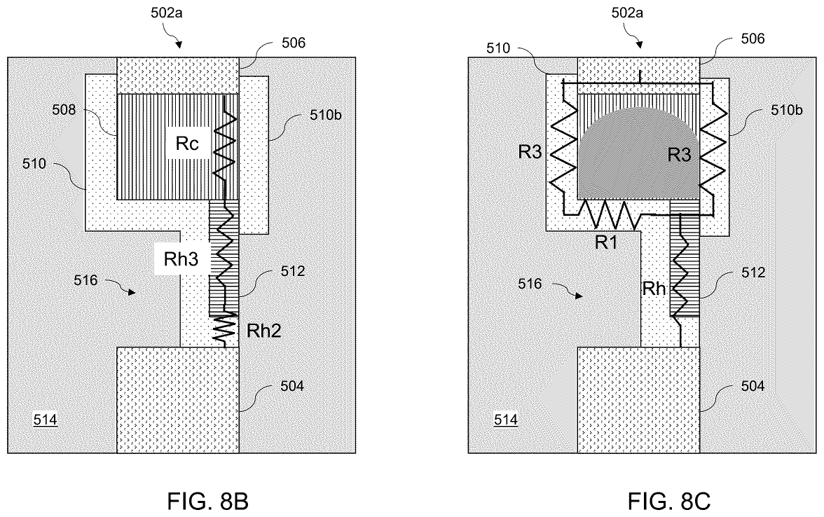

FIG. 8A is a vertical cross-sectional view of a phase-change material memory device 800 including a phase-change material memory cell 502a (also referred to as a PCRAM cell 502a) and an adjacent phase-change material memory cell 502b, according with an alternative embodiment. As shown in FIG. 8A, the PCRAM cell 502a includes an additional liner section 510b on a side of the phase-change material 508 opposite the liner 510 so that the liner 510 and the additional liner section 510b horizontally surround the phase-change material 508 on both sides of the phase-change material 508.

In embodiments in which the spacer 512 comprises SiN or another electrically insulating material, the PCRAM cell 502a may function similarly to the PCRAM cell 502a depicted in FIG. 5A. In embodiments in which re the spacer 512 comprises TiN or another electrically conducting material, the additional liner section 510b may provide a further electrical path for current to flow from the bottom electrode 504 to the top electrode 506.

FIG. 8B illustrates the PCRAM cell 502a having a TiN spacer 512 with a circuit diagram overlaid on the PCRAM cell 502a in the LRS. In FIG. 8B, the phase-change material 508 is illustrated to be in a crystalline state having a resistance Rc, such that the memory cell 502a is in the LRS. The total resistance between the bottom electrode 504 and the top electrode 506 is Rc+Rh3+Rh2, where Rh3 represents the resistance of the TiN spacer 512 portion and Rh2 that represents the resistance of the liner 510 portion between the bottom electrode 504 and the TiN spacer 512.

FIG. 8C illustrates the PCRAM cell 502a having the TiN spacer 512 with a circuit diagram overlaid on the PCRAM cell 502a in the HRS. In FIG. 8C, the phase-change material 508 is illustrated to be in the amorphous state. The total resistance between the bottom electrode 504 and the top electrode 506 is Rh+(R3+R1)/R3, where Rh represents the resistance of the heater 516 (including the spacer 512 and the portion of the liner 510 between the bottom electrode 504 and the spacer 512, R3 represents the resistance of each of the vertical portions of the liner 510 on opposite sides of the phase-change material 508, and R1 represents the resistance of the horizontal portion of the liner 510 under the phase-change material 508.

In embodiments in which the spacer 512 is formed with a TiN material and the additional liner portion 510b, the memory window for the PCRAM cell 502a may be relatively large compared to some prior designs. The difference in the resistance between the LRS and the HRS is primarily driven by the difference between the resistance of the phase-change material 508 in the crystalline state and the resistance of the liner 510. In contrast, in embodiments in which the spacer 512 is formed with a SiN material, the difference in resistance between the LRS and the HRS is primarily driven by the resistance of the liner 510 (including the additional liner portion 510b), i.e., with current traversing a longer portion of the liner 510 in the HRS.

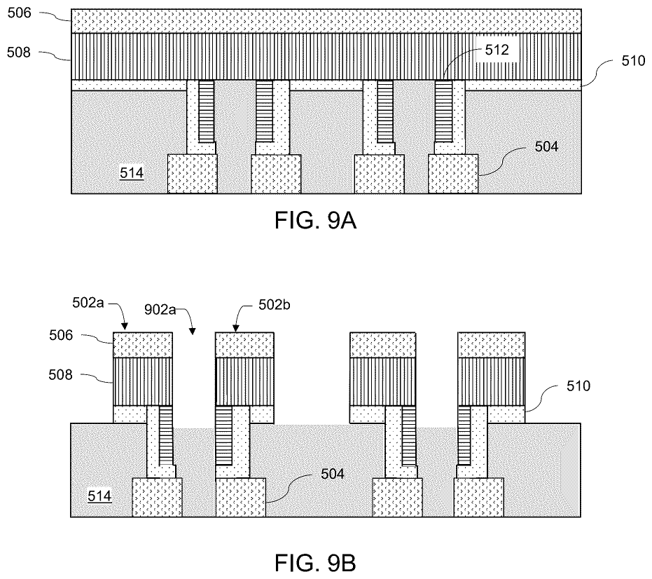

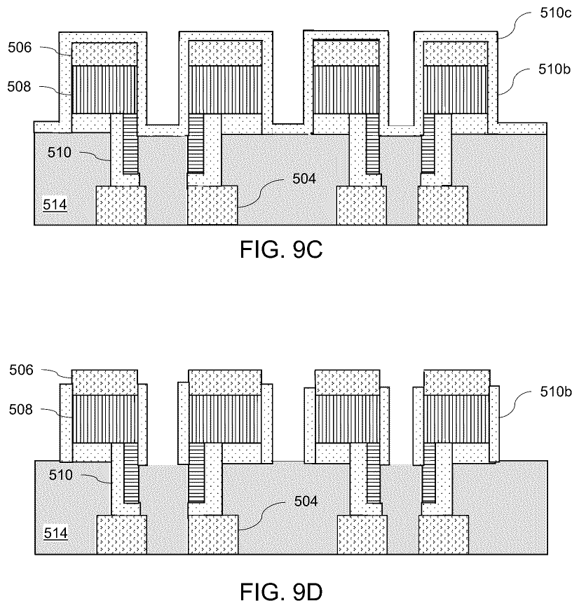

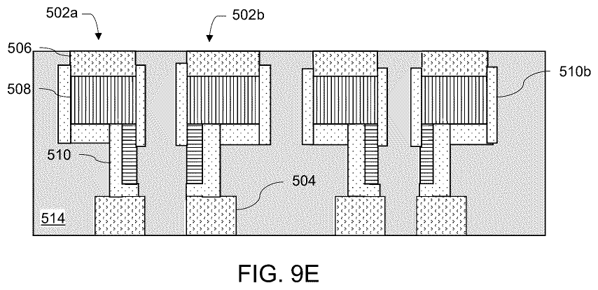

FIGS. 9A-9E illustrate a process for forming the memory cell 502a with the additional liner section 510b, in accordance with some embodiments. FIGS. 9A-9E illustrate the process by showing vertical cross-sectional view of various intermediate structures formed during performance of the process.

FIG. 9A shows the deposition of phase-change material 508 and the top electrode 506 on top of the phase-change material 508. The structure illustrated in FIG. 9A may be fabricated in the same or similar manner as shown in FIGS. 7A-7I.

FIG. 9B shows patterning and etching to define the memory cell 502a and the adjacent memory cell 502b. The etching may produce an opening 902a between the memory cell 502a and the adjacent memory cell 502b, and the opening 902a may extend to a depth at the top of the oxide layer 514.

FIG. 9C shows deposition of a layer 510c of liner material, which may form the additional liner portion 510b on the side of the phase-change material 508. The layer 510c of liner material may also cover the top of the oxide layer 514 and the top of the top electrode 506.

FIG. 9D illustrates liner spacer etching to remove the deposited layer 510c of liner material except for the additional liner portion 510b. The liner spacer etching may be performed, for example, by selectively etching the liner material to a specified depth that exposes the top of the top electrode 506 and the top of the oxide layer 514 while leaving the additional liner portion 510b.

FIG. 9E shows oxide deposition and planarization. The oxide deposition causes the oxide layer 514 to surround the memory cell 502a and the adjacent memory cell 502b.

The following discussion now refers to a number of methods and method steps. Although the method steps are discussed in specific orders or are illustrated in a flow chart as being performed in a particular order, no order is required unless expressly stated or required because a step is dependent on another step being completed prior to the step being performed.

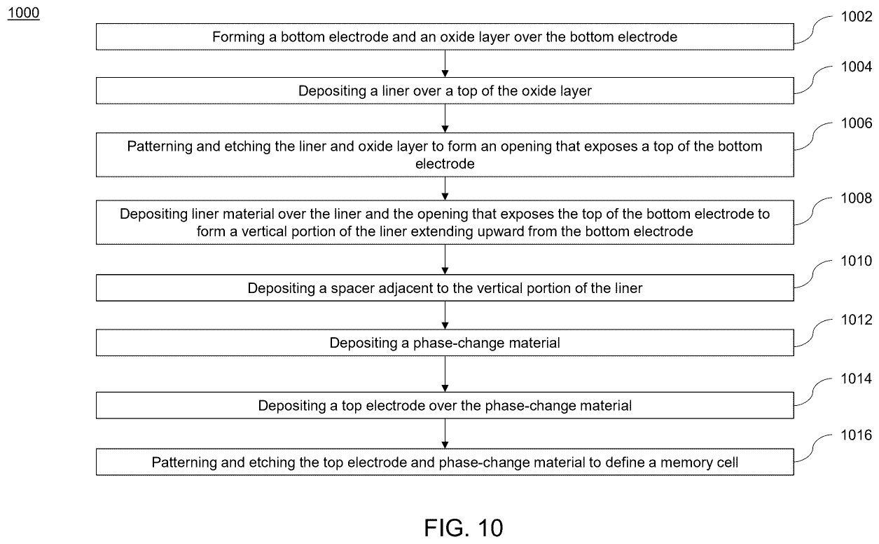

Embodiments are now described with reference to FIG. 10, which illustrates a flow diagram of an example method 1000 for fabricating a phase-change memory device 500 according to some embodiments of the present disclosure.

In an embodiment method 1000, step 1002 may include forming a bottom electrode 504 and an oxide layer 514 over the bottom electrode. In an embodiment method 1000, step 1004 may include depositing a liner 510 over a top of the oxide layer 514. In an embodiment method 1000, step 1006 may include patterning and etching the liner 510 and oxide layer 514 to form an opening 702a that exposes a top of the bottom electrode 504. In an embodiment method 1000, step 1008 may include depositing liner material 510a over the liner 510 and the opening 702a that exposes the top of the bottom electrode 504 to form a vertical portion of the liner 510 extending upward from the bottom electrode 504. The method 1000 may include depositing oxide layer material into the opening 702a and planarizing a top surface of the liner 510, the spacer 512, and the oxide layer 514.

In an embodiment method 1000, step 1010 may include depositing a spacer 512 adjacent to the vertical portion of the liner 510. Depositing the spacer 512 may include depositing a layer of spacer material and etching away horizontal portions of the spacer material on top of the liner 510.

In an embodiment method 1000, step 1012 may include depositing a phase-change material 508. In an embodiment method 1000, step 1014 may include depositing a top electrode 506 over the phase-change material 508.

In an embodiment method 1000, step 1016 may include patterning and etching the top electrode 506 and the phase-change material 508 to define a memory cell 502a. Patterning and etching the top electrode 506 and phase-change material 508 to define a memory cell 502a may include creating an opening 704a, 704b in the top electrode 506 and phase-change material 508 to a depth that reaches the oxide layer 514 and depositing another layer of liner material such that the phase-change material 508 and the top electrode 506 are surrounded by the liner 510.

Patterning and etching the top electrode 506 and phase-change material 508 to define a memory cell 502a may further include etching the liner 510 to expose a top surface of the top electrode 506. Defining the memory cell 502a may include patterning and etching the top electrode 506 and the phase-change material 508 to create an opening 710 between the memory cell 502a and an adjacent memory cell 502b, depositing further oxide layer material, and performing planarization on the top surface of the top electrode 506 and the top surface of the oxide layer 514.

The various embodiments disclosed herein may provide various advantages and improvements. A phase-change memory device may have a larger memory window, a highly reliable resistance state, and a lower required write power. A small heater is fabricated from the same material and process as a liner for a phase-change material. The process for creating the liner defines the heater dimensions and may be cost-effective. A spacer may be included in the structure of the heater; for example, a TiN spacer may result in a lower resistance heater and a SiN heater may result in a higher resistance heater. The phase-change memory device may be suitable for MLC operation where a larger memory window may be desirable.

In some embodiments, a phase-change memory device 500 includes a bottom electrode 504, a top electrode 506, and a phase-change material 508 disposed between the top electrode 506 and the bottom electrode 504. The phase-change memory device 500 includes a liner 510 extending from the bottom electrode 504 along at least one side of the phase-change material 508 to the top electrode 506. The phase-change memory device 500 includes a heater 516 comprising a vertical portion of the liner 510 extending upward from the bottom electrode 504 toward the phase-change material 508. The phase-change memory device 500 includes a spacer 512 positioned adjacent to the vertical portion of the liner 510.

In an embodiment, the spacer 512 comprises TiN and the heater 514 comprises a vertical portion of the spacer extending upward from the bottom electrode toward the phase-changed material. In an embodiment, the spacer 512 comprises SiN. In an embodiment, the liner 510 comprises a material with a resistivity in the range of 0.1 to 100 ohm·cm. In an embodiment, the liner 510 comprises one of tantalum nitride (TaN), titanium nitride (TiN), or silicon oxynitride (SiON). In an embodiment, the phase-change memory device 500 includes an oxide layer 514 enclosing the bottom electrode 504 and the top electrode 506 on left and right sides of the bottom electrode 504 and the top electrode 506. In an embodiment, the phase-change material 508 comprises one of a germanium-antimony-tellurium alloy or an aluminum-antimony alloy.

In some embodiments, a phase-change memory device 500 includes a bottom electrode 504, a top electrode 506, and a phase-change material 508 disposed between the top electrode 506 and the bottom electrode 504. The phase-change material 508 is configured to switch between an amorphous state and a crystalline state in response to heating. The phase-change memory device 500 includes a liner 510 extending from the bottom electrode 504 along a first side of the phase-change material 508 to the top electrode 506. The phase-change memory device 500 includes an additional liner section 510b extending along a second side of the phase-change material 508. The second side is horizontally opposite the first side.

In an embodiment, the phase-change memory device 500 includes a heater 516 disposed between the bottom electrode 504 and the phase-change material 508. In an embodiment, the heater includes a vertical portion of the liner 510 extending upward from the bottom electrode toward the phase-change material 508. In an embodiment, the phase-change memory device 500 includes a spacer 512 positioned adjacent to the vertical portion of the liner 510, wherein the spacer 512 comprises TiN and the heater 516 comprises a vertical portion of the spacer 512 extending upward from the bottom electrode 504 toward the phase-changed material 508. In an embodiment, the phase-change memory device 500 includes a spacer 512 positioned adjacent to the vertical portion of the liner, wherein the spacer comprises SiN. In an embodiment, the liner 510 and the additional liner section 510b comprise a material with a resistivity in the range of 0.1 to 100 ohm·cm.

In some embodiments, a method 1000 for fabricating a phase-change memory device 500 includes forming a bottom electrode 504 and an oxide layer 514 over the bottom electrode 504. The method 1000 includes depositing a liner 510 over a top of the oxide layer 514. The method 1000 includes patterning and etching the liner 510 and oxide layer 514 to form an opening 702a that exposes a top of the bottom electrode 504. The method 1000 includes depositing liner material over the liner 510 and the opening 702a that exposes the top of the bottom electrode 504 to form a vertical portion of the liner 510 extending upward from the bottom electrode 504. The method 1000 includes depositing a spacer 512 adjacent to the vertical portion of the liner 510. The method 1000 includes depositing a phase-change material 508. The method 1000 includes depositing a top electrode 506 over the phase-change material 508. The method 1000 includes patterning and etching the top electrode 506 and the phase-change material 508 to define a PCRAM cell.

In an embodiment, depositing the spacer 512 adjacent to the vertical portion of the liner 510 comprises: depositing a layer of spacer material; and etching away horizontal portions of the spacer material on top of the liner 510. In an embodiment, the method 1000 further comprises depositing oxide layer material into the opening 702a and planarizing a top surface of the liner 510, the spacer 512, and the oxide layer 514. In an embodiment, patterning and etching the top electrode 506 and the phase-change material 508 to define a memory cell comprises creating an opening 710 in the top electrode 506 and the phase-change material 508 to a depth that reaches the oxide layer 514. In an embodiment, the method 1000 includes depositing another layer of liner material such that the phase-change material 508 and the top electrode 506 are surrounded by the liner 510. In an embodiment, the method 1000 includes etching the liner 510 to expose a top surface of the top electrode 506. In an embodiment, the method 1000 includes patterning and etching the top electrode 506 and the phase-change material 508 to create an opening 710 between the memory cell 502a and an adjacent memory cell 502b, depositing further oxide layer material, and performing planarization of the top surface of the top electrode 506 and the top surface of the oxide layer 514.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A phase-change memory device comprising:
a bottom electrode;
a top electrode;
a phase-change material disposed between the top electrode and the bottom electrode;
a liner extending from the bottom electrode along at least one side of the phase-change material to the top electrode;
a heater comprising a vertical portion of the liner extending upward from the bottom electrode toward the phase-change material; and
a spacer positioned adjacent to the vertical portion of the liner.

2. The phase-change memory device of claim 1, wherein the spacer comprises TiN and the heater comprises a vertical portion of the spacer extending upward from the bottom electrode toward the phase-changed material.

3. The phase-change memory device of claim 1, wherein the spacer comprises SiN.

4. The phase-change memory device of claim 1, wherein the liner comprises a material with a resistivity in a range of 0.1 to 100 ohm·cm.

5. The phase-change memory device of claim 1, wherein the liner comprises one of tantalum nitride (TaN), titanium nitride (TiN), or silicon oxynitride (SiON).

6. The phase-change memory device of claim 1, comprising an oxide layer enclosing the bottom electrode and the top electrode on left and right sides of the bottom electrode and the top electrode.

7. The phase-change memory device of claim 1, wherein the phase-change material comprises one of a germanium-antimony-tellurium alloy or an aluminum-antimony alloy.

8. A phase-change memory device comprising:
a bottom electrode;
a top electrode;
a phase-change material disposed between the top electrode and the bottom electrode, the phase-change material configured to switch between an amorphous state and a crystalline state in response to heating;
a liner extending from the bottom electrode along a first side of the phase-change material to the top electrode; and
an additional liner section extending along a second side of the phase-change material to the top electrode, wherein the second side is horizontally opposite the first side.

9. The phase-change memory device of claim 8, comprising a heater disposed between the bottom electrode and the phase-change material.

10. The phase-change memory device of claim 9, wherein the heater comprises a vertical portion of the liner extending upward from the bottom electrode toward the phase-change material.

11. The phase-change memory device of claim 10, comprising a spacer positioned adjacent to the vertical portion of the liner, wherein the spacer comprises TiN and the heater comprises a vertical portion of the spacer extending upward from the bottom electrode toward the phase-changed material.

12. The phase-change memory device of claim 10, comprising a spacer positioned adjacent to the vertical portion of the liner, wherein the spacer comprises SiN.

13. The phase-change memory device of claim 8, wherein the liner and the additional liner section comprise a material with a resistivity in a range of 0.1 to 100 ohm·cm.

14. A method for fabricating a phase-change memory device, the method comprising:
forming a bottom electrode and an oxide layer over the bottom electrode;
depositing a liner over a top of the oxide layer;
patterning and etching the liner and oxide layer to form an opening that exposes a top of the bottom electrode;
depositing liner material over the liner and the opening that exposes the top of the bottom electrode to form a vertical portion of the liner extending upward from the bottom electrode;
depositing a spacer adjacent to the vertical portion of the liner;
depositing a phase-change material;
depositing a top electrode over the phase-change material; and
patterning and etching the top electrode and the phase-change material to define a PCRAM cell.

15. The method of claim 14, wherein depositing the spacer adjacent to the vertical portion of the liner comprises:
depositing a layer of spacer material; and
etching away horizontal portions of the spacer material on top of the liner.

16. The method of claim 14, further comprising:
depositing oxide layer material into the opening; and
planarizing a top surface of the liner, the spacer, and the oxide layer.

17. The method of claim 14, wherein patterning and etching the top electrode and phase-change material to define a memory cell comprises creating an opening in the top electrode and the phase-change material to a depth that reaches the oxide layer.

18. The method of claim 17, comprising depositing another layer of liner material such that the phase-change material and the top electrode are surrounded by the liner.

19. The method of claim 18, comprising etching the liner to expose a top surface of the top electrode.

20. The method of claim 19, comprising patterning and etching the top electrode and the phase-change material to create an opening between the memory cell and an adjacent memory cell, depositing further oxide layer material, and performing planarization on the top surface of the top electrode and the top surface of the oxide layer.
